(19) United States
(12) Patent Application Publication
(10) Pub. No.: US 2019/0057842 A1
(43) Pub. Date: Feb. 21, 2019

(54) RF SIGNAL TRANSMITTING DEVICE USED IN PLASMA PROCESSING APPARATUS

(71) Applicant: PIOTECH CO., LTD., Shenyang (CN)

(72) Inventor: JUNICHI ARAMI, Shenyang (CN)

(21) Appl. No.: 16/104,184

(22) Filed: Aug. 17, 2018

(30) Foreign Application Priority Data
Aug. 17, 2017 (CN) 201710705141.7

(51) Int. Cl. H01J 37/32

(52) U.S. Cl. CPC H01J 37/32183; H01J 37/32724

(57) ABSTRACT

The invention provides an RF signal transmitting device for plasma processing apparatus. The device includes a metal layer embedded in a plate and a metal rod for transmitting RF signal. The metal rod is provided with an upper end and a lower end. The upper end of the metal rod electrically coupled to the metal layer. A magnetic metal contact is sandwiched between the upper end of the metal rod and the metal layer. The material of metal rod is selected from the group of tungsten and chromium.

### CROSS-REFERENCE TO RELATED APPLICATIONS

This non-provisional application claims priority under 35 U.S.C. § 119(a) on Patent Application No(s). 201710705141.7 filed in China on Aug. 17, 2017, the entire contents of which are hereby incorporated by reference.

### BACKGROUND

### Technical Field

The present disclosure relates to an RF (radiofrequency) device used in wafer processing apparatus, and more particularly, to an RF signal transmitting device used in plasma processing apparatus.

### Description of Related Art

Plasma processing equipment used for wafer processing typically includes an RF control circuit. The RF control circuit is configured to provide and transmit RF signals to electrodes in the plasma processing equipment, thereby generating an electric field within a processing area in a vacuum processing chamber. In the electric field, reagent gases are ionized and involved in various reactions, such as etching or deposition, with wafers waiting to be processed. Typically, an RF control circuit includes an RF signal generator and an impedance matching circuit, in which the impedance matching circuit comprises a resistor, a capacitor, an inductor or a combination thereof. The impedance matching circuit is appropriately configured so that the impedance of an RF signal source is matched with that of the load. The impedance matching circuit receives RF signals from the RF signal generator, and the signals are modulated within the circuit in order to be provided to the plasma processing equipment.

The RF circuit is coupled to the electrodes of the plasma processing equipment, in particular through a cable or an RF transmission path formed by a conductive connecting structure, so that the RF signals can be transmitted to the electrodes successfully. In a prior art configuration, applying excessive magnetic materials to an RF circuit, which includes an RF transmission path, is usually avoided, for magnetic materials may cause energy loss, such as eddy current loss and hysteresis loss. Energy loss may have an impact on the RF signals provided to the plasma processing equipment or to the vacuum chamber, resulting in plasma scattering.

Methods for reducing such energy loss have been found in prior art disclosures, such as U.S. Pat. No. 6,280,563 B1, which discloses a plasma device in a vacuum chamber, the plasma device comprising a powered non-magnetic metal member located between a source of the excitation and the plasma, wherein said non-magnetic metal member has openings for disrupting eddy currents. Furthermore, U.S. Patent Application No. 20070044915A1 relates to a vacuum plasma processor and discloses a method for reducing eddy current losses through the configuration of a non-magnetic metal backplane and a Faraday shield.

It is essential to reduce such losses in loops within an RF control circuit, so that the plasma processing environment would become stable. However, it is still not an easy task to completely avoid the application of magnetic metals within a complex circuit loop. In this regard, there is a need to develop an RF signal transmitting device with a structure that may include magnetic metals without having an impact on energy loss or creating interference.

### SUMMARY

An object of the present disclosure is to provide an RF signal transmitting device used in plasma processing equipment, wherein the RF signal transmitting device comprises a metal layer and a metal rod. The metal layer is enclosed in a plate, the metal rod is used for transmitting RF signals, and a magnetic metal contact is disposed between an upper end of the metal rod and the metal layer.

Another object of the present disclosure is to provide plasma processing apparatus, which comprises a housing and a heater base. The heater base comprises a plate and a column, wherein the plate encloses a heating unit and a metal layer used for transmitting RF signals, and the column extends from the bottom of the housing in order to support the plate within the housing. Furthermore, the column encloses a first metal rod having an upper end and a lower end, wherein the upper end of the first metal rod is electrically coupled to the metal layer, and a magnetic metal contact is disposed between the upper end of the first metal rod and the metal layer.

In one embodiment, said metal layer is made of tungsten, and said metal rod is made of tungsten or chromium.

In one embodiment, said magnetic metal contact is made of nickel.

In one embodiment, the column of the heater base further encloses a second metal rod, which is electrically coupled to the heating unit of the plate.

The foregoing and other features and advantages of the present disclosure will be described in detail in the following detailed descriptions of several embodiments as well as in the accompanying drawings illustrating the principles of the invention.

### BRIEF DESCRIPTION OF THE DRAWINGS

Aspects of the disclosure can be better understood with reference to the following drawings. Non-limiting and non-exhaustive embodiments are described with reference to the following drawings. The components in the drawings are not necessarily to scale, with the emphasis instead being placed upon illustrating the structure and principles of the invention.

FIG. 1A is a block diagram showing an embodiment of the plasma processing apparatus according to the present disclosure (the RF control circuit being electrically coupled to an upper electrode).

FIG. 1B is a block diagram showing another embodiment of the plasma processing apparatus according to the present disclosure (the RF control circuit being electrically coupled to a lower electrode).

FIG. 2 is a sectional view showing the internal structure of a heater in the plasma processing apparatus according to the present disclosure.

### DETAILED DESCRIPTION

The present disclosure will be fully described with reference to the drawings showing illustrated embodiments of the invention. However, given that this claimed subject matter can be achieved through various forms, the construction of the subject matter being covered or filed is not limited to any illustrated embodiments disclosed herein, which are merely illustrative. Similarly, the present disclosure aims to provide a reasonably wide scope to the claimed subject matter being filed or covered. Furthermore, illustrated embodiments of the claimed subject matter can be, for example, a method, a device or a system. Therefore, these embodiments may be implemented in hardware, software, firmware or any form of combination thereof (which is, as it is known, not software).

Appearances of the phrase “in one embodiment” herein are not necessarily referring to the same embodiment, and appearances of the phrase “in other embodiments” herein are not necessarily referring to a different embodiment. This for the purpose of, for example, stating that the claimed subject matter includes combinations of all or part of the illustrated embodiments.

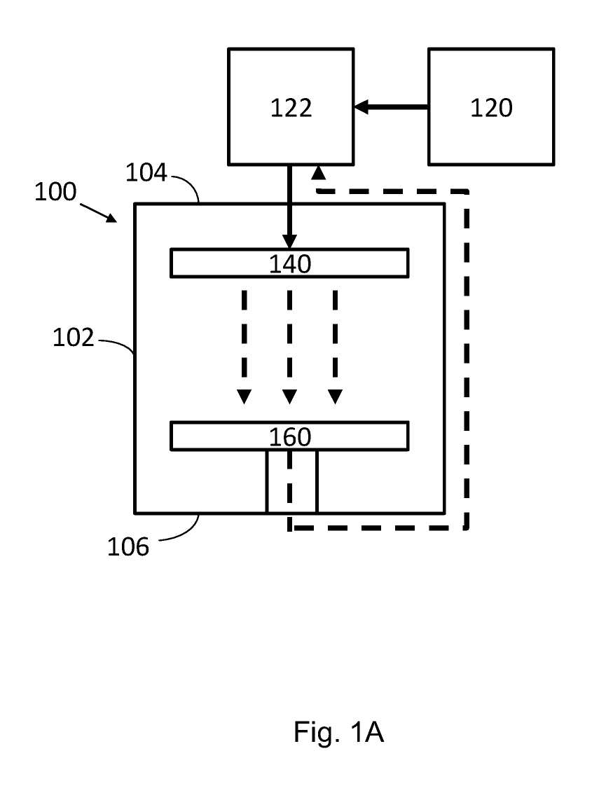

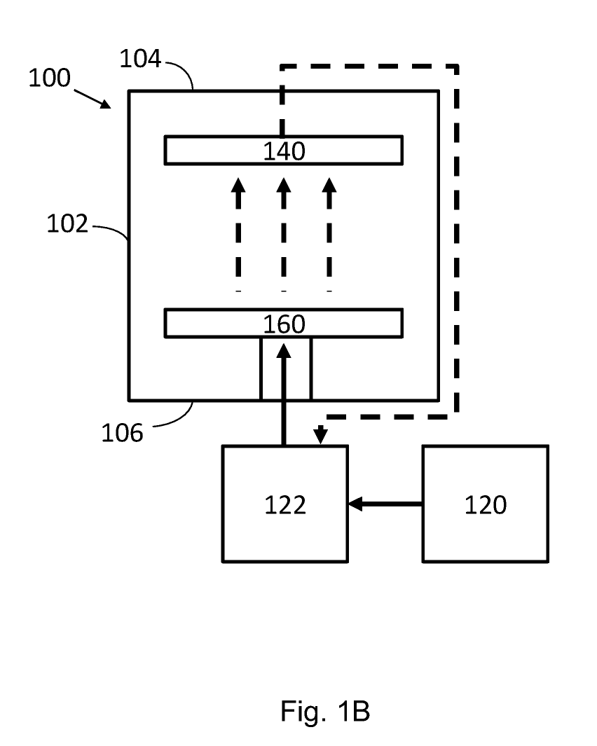

FIGS. 1A and 1B are schematic views showing two embodiments of the plasma processing apparatus according to the present disclosure. In these two embodiments, said plasma processing apparatus includes a housing 100, which forms a chamber for accommodating various devices and components used for plasma processing. The housing 100 has a side wall 102, a top 104 and a bottom 106. Typically, the side wall 102 can be connected to an exhaust system (not shown), which is configured to control the pressure inside the chamber; the top 104 can be connected to a gas supply system (not shown), which is configured to supply reagent gases to the chamber; and the bottom 106 can be connected to a motor drive (not shown) and a support component (not shown), both of which are configured to support the wafers being transported into the chamber. All or at least part of the housing 100 serves as a conductor.

The plasma processing apparatus according to the present disclosure includes a plasma control device. As shown in the drawings, said plasma control device includes an RF signal generator 120 and a matchbox 122. An output of the RF signal generator 120 is electrically coupled to an input of the matchbox 122. An output of the matchbox 122 is electrically coupled to an electrode within the housing 100. As shown in FIG. 1A, an upper electrode 140 is provided within the housing 100 near the top 104, with the matchbox 122 being electrically coupled to the upper electrode 140. For example, the matchbox 122 can pass through the housing 100 and be coupled to the upper electrode 140 via a conducting wire. As shown in FIG. 1B, a pedestal 160 is also provided within the housing 100 near the bottom 106, and includes a lower electrode (not shown in FIG. 1B), with the matchbox 122 being electrically coupled to said lower electrode.

The RF signal generator 120 is configured to generate one or more RF signals (RF voltage). In one embodiment, the RF signal generator 120 can include one or more RF signal generating units, wherein each of the RF signal generating units has a unique working frequency. According to prior art techniques, the RF signal generator 120 may be implemented through at least one low-frequency RF signal generating unit and at least one high-frequency RF signal generating unit.

The matchbox 122 is configured to achieve an impedance match between the RF signal generator 120 and a load end (all types of impedance within the housing), and includes an impedance matching circuit. According to prior art techniques, said impedance match can be achieved by controlling a reactance of the impedance matching circuit via a control method. The impedance matching circuit receives one or more RF signals from the RF signal generator 122, integrates the signals into one RF signal suitable for plasma processing, and provides such RF signal to the upper or lower electrode within the housing 100.

In one embodiment, said plasma control device is also electrically coupled to the housing 100. According to the configuration in FIG. 1A, when the matchbox 122 is coupled to the upper electrode 140, the lower electrode of the pedestal 160 is electrically coupled to the housing 100 through a connector (not shown) provided near the bottom 106. According to the configuration in FIG. 1B, when the matchbox 122 is coupled to the lower electrode of the pedestal 160, the upper electrode 140 is electrically coupled to the housing 100 through a connector (not shown) provided near the top 104.

In view of the above, the RF signal being supplied may generate a certain electrical field within a processing area located between the upper and lower electrodes within the chamber (as illustrated by the dashed lines situated between the upper and lower electrodes in FIGS. 1A and 1B), so that the reagent gases within the area can be ionized and then applied to various processing reactions, such as etching or deposition. The RF signal that runs through the upper and lower electrodes can return to the matchbox 122 via a return path extending along the housing 100 (as illustrated in FIGS. 1A and 1B by the dashed lines extending from the inside to the outside of the housing). As shown in FIG. 1A, when the RF voltage is applied to the upper electrode 140, the lower electrode can be configured as a ground electrode or configured to offer a reference voltage. Conversely, when the RF voltage is applied to the lower electrode, the upper electrode can be configured as a ground electrode or configured to offer a reference voltage. Thus, the direction of the electric field shown in FIG. 1A is the opposite of that in FIG. 1B.

The pedestal 160 is mainly used for supporting a workpiece (not shown), such as a wafer. As mentioned above, the pedestal 160 according to the present disclosure includes an electrode that can conduct plasma processing or provide electrostatic chuck forces depending on operation needs. In one embodiment, the pedestal 160 can be a heater base that includes one or more heating units, which can perform heat-treating operations on the workpiece.

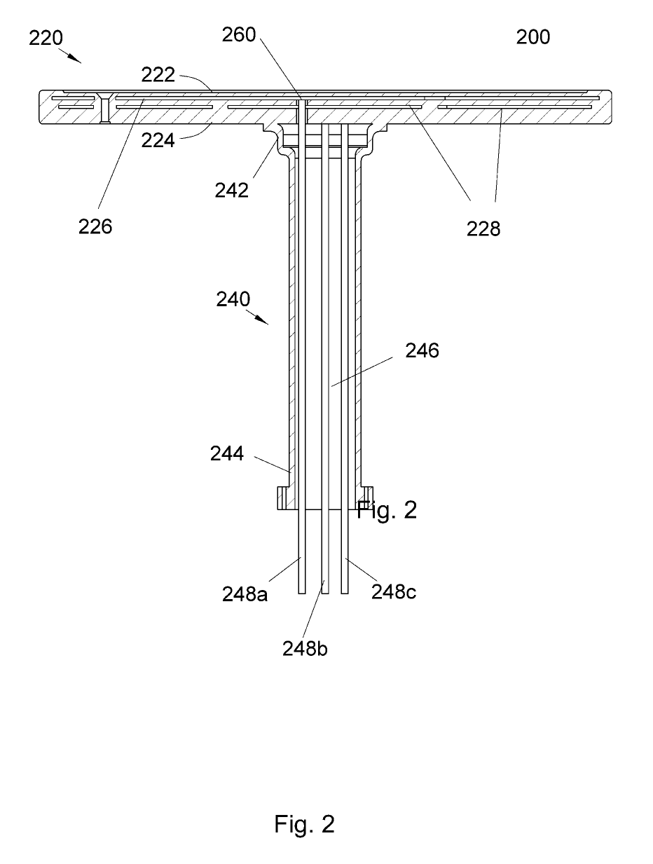

FIG. 2 shows another embodiment of the pedestal shown in FIG. 1. The pedestal 200 in FIG. 2 comprises a plate 220 and a column 240. The plate 220 has a substantially circular shape, and has a top surface 222 and a bottom surface 224. The plate 220 has a thickness extending between the top surface 222 and the bottom surface 224. The top surface 222 faces toward the plasma processing area and is used for supporting the workpiece waiting to be processed. The bottom surface 224 is positioned opposite to the top surface 222 and faces toward the bottom (such as the bottom 106 in FIGS. 1A and 1B) of the housing. The column 240 has an upper end 242 and a lower end 244, with a length of the column 240 extending between the upper end 242 and the lower end 244. The upper end 242 of the rod is combined with the bottom surface 224 of the plate. The plate 220 and the column 240 can be formed in one piece, by, for example, manufacturing both at the same time in ceramics, or combining both with a prior art structuring method.

The plate 220 according to the present disclosure encloses a metal layer 226 that is located near the top surface 222 and extends substantially parallel to the top surface 222. The metal layer 226 can be used, depending on operation needs, as an electrode or electrostatic chuck. In a preferred embodiment, the metal layer 226 is made of tungsten. When used as an electrode, the metal layer 226 is used for transmitting RF signals. When used as a lower electrode like the electrode 160 shown in FIG. 1A, the metal layer 226 has a ground potential or a reference potential. When used as a lower electrode like the electrode 160 shown in FIG. 1B, the metal layer 226 has an RF potential.

The plate 220 as shown in FIG. 2 further encloses at least one heating unit 228, which is configured to operate by receiving control signals. The heating unit 228 is located below the metal layer 226 and spreads substantially along the direction in which the top surface 222 extends, so that the metal layer 226 is located between the top surface 222 and the heating unit 228. According to prior art techniques, the heating unit 228 is implemented using a resistance heating component, such as by using a spiral spring-shaped component that extends within a significant area, so that an even heat distribution along the top surface 222 of the plate 220 is achieved. The plate 220 can include multiple heating units, each of which is controlled individually. For example, a central heating unit can be configured near the center of the plate, and a peripheral heating unit can be configured near the periphery of the plate. In other embodiments, the plate according to the present disclosure does not include heating units.

The column 240 extends from the bottom 106 of the housing 100 shown in FIGS. 1A and 1B, in order to support the plate 220 within the housing. As shown in the FIG. 2, the column 240 is a hollow rod that has a channel 246 extending between the upper end 242 and the lower end 244 of the rod. In other embodiments, the rod can have a non-hollow structure. As shown in FIG. 2, the column 240 encloses multiple metal rods 248a, 248b and 248c, which extend within the column 240. Each of said metal rods has an upper end and a lower end, and has a length extending between the upper and the lower end. The upper ends of the metal rods extend from the upper end 242 of the rod into the plate 220, while the lower ends of the metal rods extend from the lower end 244 of the rod toward the bottom 106 of the housing shown in FIGS. 1A and 1B. Specifically, the upper end of the first metal rod 248a extends into the plate 220 and is electrically coupled to the metal layer 226; the upper ends of the second metal rod 248b and the third metal rod 248c extend into the plate 220 and are electrically coupled to the heating unit 228. In one embodiment, the first metal rod 248a can be made of tungsten or chromium, and the second metal rod 248b and third metal rod 248c are made of nickel.

The upper end of the first metal rod 248a can directly touch a bottom surface of the metal layer 226. In other embodiments, a connector (not shown) may be provided within the plate 220, thereby coupling electrically the upper end of the first metal rod 248a to a bottom surface of the metal layer 226. In a preferred embodiment, a magnetic metal contact is disposed between the upper end of the first metal rod 248a and the metal layer 226, which is a contact formed through welding. As shown in FIG. 2, the magnetic metal contact 260 is located between the first metal rod 248a and the metal layer 226 and connects these two components. The magnetic metal contact 260 is formed through a brazing process, in which nickel is used as the filler metal. As a result, the magnetic metal contact (i.e. the brazing surface) that is formed is a contact made of nickel.

The upper ends of the second metal rod 248b and the third metal rod 248c can be connected directly to the heating unit 228 using prior art techniques. In one embodiment, the second metal rod 248b is electrically connected to said central heating unit, and the third metal rod 248c is electrically connected to said peripheral heating unit. In other embodiments, the number of metal rods and heating units can be greater or less, and is not limited to that shown in the illustrated embodiments.

The first metal rod 248a is electrically coupled to said plasma control device. In the configuration shown in FIG. 1A, the lower end of the first metal rod 248a is electrically coupled to the bottom 106 of the housing 100. In one embodiment, the lower end of the first metal rod 248a is electrically coupled to the housing 100 via a conductive component (not shown), so that the RF signals that run through the upper and lower electrodes enter the return paths shown in FIGS. 1A and 1B. In the configuration shown in FIG. 1B, the lower end of the first metal rod 248a is electrically coupled to an output of the matchbox 122. In one embodiment, a conductive unit (not shown) may be provided between the first metal rod 248a and the matchbox 122, so that the first metal rod 248a receives and transmits RF signals used for plasma processing. In other embodiments, when used in the configuration shown in FIG. 1A or FIG. 1B, the first metal rod 248a may also be electrically coupled to other signal sources, such as a DC signal source, to fulfill other purposes of operation.

The length of said metal rod can be properly determined depending on whether the lower end of the metal rod should run through the bottom of the housing. With regard to the configurations shown in FIGS. 1A and 1B, in other embodiments, the column 240 of the pedestal 200 can be connected to a motor drive, so that the pedestal 200 can move vertically or rotate within the chamber while maintaining the electrical coupling between these metal rods. In one embodiment, a jacket can be provided to envelop the segment between the upper and lower ends of the metal rods, in order to avoid interference between adjacent metal rods. Said jacket can be made from an insulating material.

Although certain details have been used to describe the present disclosure for a better understanding, it will be appreciated that certain changes and modifications may be made thereto within the scope of the claims. Therefore, the foregoing embodiments are presented merely as an exemplary and are not intended to limit the present disclosure. Also, the present disclosure is not limited by the details in the description herein, but allows to be modified within the scope of the appended claims and their equivalents.

What is claimed is:

1. An RF signal transmitting device for a plasma processing apparatus, comprising:
a metal layer embedded in a plate; and
a metal rod configured to transmit RF signal, having an upper end and a lower end, the upper end of the metal rod being electrically coupled to the metal layer, and a magnetic metal contact being sandwiched between the metal layer and the metal rod.

2. The RF signal transmitting device as claimed in claim 1, wherein the metal layer is made of tungsten, and the metal rod is made of tungsten or chromium.

3. The RF signal transmitting device as claimed in claim 1, wherein the magnetic metal contact is made of nickel.

4. The RF signal transmitting device as claimed in claim 1, wherein the plate includes a heating unit.

5. A plasma processing apparatus, comprising:
a housing having a bottom; and
a heating pedestal, comprising:
a plate having a metal layer for transmitting RF signal and a heating unit enclosed therein; and
a column extending from the bottom to support the plate within the housing, the column having a first metal rod enclosed therein, the first metal rod having an upper end and a lower end, the upper end of the first metal rod being electrically coupled to the metal layer and a magnetic metal contact is sandwiched between the first metal rod and the metal layer.

6. The plasma processing apparatus as claimed in claim 5, wherein the metal layer is made of tungsten, and the first metal rod is made of tungsten or chromium.

7. The plasma processing apparatus as claimed in claim 5, wherein the magnetic metal contact is made of nickel.

8. The plasma processing apparatus as claimed in claim 5, wherein the column of the heating pedestal having a second metal rod electrically coupled to the heating unit of the plate.
